(19) United States
(12) Patent Application Publication
(10) Pub. No.: US 2025/0368855 A1
(43) Pub. Date: Dec. 4, 2025

(54) An electron conducting coating

(71) Applicant: OrganoGraph AB, Sundsvall (SE)

(72) Inventors: Armando CORDOVA, Stockholm (SE); Rana ALIMOHAMMADZADEH, Sundsvall (SE); Nicklas BLOMQUIST, Njurunda (SE)

(73) Assignee: OrganoGraph AB, Sundsvall (SE)

(21) Appl. No.: 18/876,397

(22) PCT Filed: Jun. 20, 2023
(86) PCT No.: PCT/EP2023/066699

§ 371 Date: Dec. 18, 2024

(30) Foreign Application Priority Data
Jun. 22, 2022 (SE) 2250771-9

(51) Int. Cl. C09D 183/06; C09D 1/00; C09D 7/61; C09D 7/63; C09D 7/65

(52) U.S. Cl. CPC C09D 183/06; C09D 1/00; C09D 7/61; C09D 7/63; C09D 7/65

(57) ABSTRACT

The present invention relates to a coating comprising a first coating prepared from a first composition comprising a polymerized C₁₀₋₃₀alkanetriC₁₋₅alkoxysilane, a surfactant, an organic acid catalyst and water, and optionally an inorganic component and a second coating prepared from a second composition comprising a graphene, nanographite, nanographene or an electron conducting polymer. The invention also relates to a process for manufacturing said coating. The invention also relates to uses of the coating as a water repellant coating, and/or electron conducting, and/or as a mold-resistant coating and/or as a fire-resistant coating on organic or inorganic surfaces.

### FIELD OF THE INVENTION

The present invention relates to an electron conducting coating comprising a first coating prepared from a first composition comprising a polymerized C₁₀₋₃₀alkanetriC₁₋₅alkoxysilane, a surfactant, an organic acid catalyst and water, and optionally an inorganic component and a second coating prepared from a second composition comprising a graphene, nanographite or an electron conducting polymer. The invention also relates to a process for manufacturing said coating. The invention also relates to uses of the coating as a water repellant coating, and/or electron conducting, and/or as a mold-resistant coating and/or as a fire-resistant coating on organic or inorganic surfaces.

### BACKGROUND OF THE INVENTION AND PRIOR ART

Coating is applying a layer or film on a surface of an object, such as metal, plastic, paper, or wood. The layer, film or coating may be functionalized by creating specific properties or functions on the coating. The coating may for example be made of electronic conducting or hydrophobic, lipophobic or optical properties.

A lot of research has been performed on the development of hydrophobic surfaces, especially for use on fabrics to make the fabrics hydrophobic. Other research has been directed to fire resistance coatings and coatings having anti-microbial properties. Many of these coatings, however, contain poly-fluoro-alkanes, e.g. PFAS. These fluoro-alkanes may cause severe damage to humans and nature.

Roughness of a coating may be important to prevent slipping and scratching of a surface. Evenness of a rough coating is important for the mechanical and chemical stability of the coating as well as for the aesthetic appearance of a coating.

Due to the material geometry of nanostructured materials, such as graphene and nanographite, its suspension rheology is complex and challenging to coat in a roll-to-roll process with sufficient coating thickness. Aqueous suspensions with these materials obtain high viscosity at low solids contents and the coating suspension can thus often contain 90 wt % water or more. The high amount of water is problematic when coating water-absorbent materials, such as paper, as it causes dimensional changes in the substrate, which leads to wrinkles and also cracks in the coating. The large amount of water that is absorbed also requires a lot of energy in the drying process, which is to be avoided, especially for large scale production.

Thermal, chemical, and mechanical stability of a coating ensures durability and are important measures for the quality of a coating.

Degradation products of a coating must be environmentally stable.

Coatings may be manufactured using different processes. For large scale production and scalability, the process time is preferably short and without use of high temperatures and high pressure. In most known processes, solvents are used, such as alcohols, ammonia, ammonium hydroxide, sulfonates, amides. Many such solvents are volatile, flammable, corrosive and harmful to humans and nature. For large scale production, such solvents are preferably avoided.

Applying the coating on a surface should preferably be done in a simple and inexpensive manner. Most known coatings are complex, expensive, time consuming and costly to apply and do not provide a rough surface of the coating.

The manufacturing of modified silanized silica or modified silanized cellulose is often complex and expensive.

CN110157221A discloses a method for preparing a nanometer ceramic conductive coating, comprising the following steps: step one, a nano-silica (silicon dioxide) is hydrophobic treated with a silane in the presence of catalyst to obtain a nanometer ceramic resin; step two, adding conductive filler in the nanometer ceramic resin, non-conductive fillers and pigments and dispersing at high speed to obtain the finished product. The nano-ceramic conductive coating has high polarity and anti-electrostatic properties and good compatibility with most conductive fillers. A conductive paint prepared by the invention has superior conductivity, lasting stable conductivity, hardness, wear resistance, temperature resistance, antifouling, waterproof, anti-aging and so on, it is especially suitable for anti-static floor, anti-static coating, and high temperature occasion.

In the first step water and surfactant are absent and in the second step additional ingredients non-conductive fillers and pigments are present. Also, the nano-ceramic conductive paint is not applied to paper.

CN107326651B discloses a multifunctional super-hydrophobic textile finishing agent, preparation method and application thereof.

CN109811586B discloses a method for preparing super-hydrophobic coating by laser printing comprising preparation of super-hydrophobic nanocomposite by adding a catalyst (hydrochloric acid, nitric acid, sulfuric acid, acetic acid, oxalic acid, formic acid, benzenesulfonic acid, ammonia water, ethylenediamine, triethylamine and butylamines), water, organosilane and nanoparticles (graphene oxide, silicon dioxide) in an alcohol solvent, stirring and reacting at 25 to 100 DEG C for 1 to 72 h. After the reaction, centrifuging and drying to obtain a super-hydrophobic nano-composite. Mixed ball milling is carried out on the super-hydrophobic nano composite, while adding resin (acrylate or polystyreine, etc.) and carbon powder. to obtain uniform super-hydrophobic carbon powder, super-hydrophobic carbon powder is loaded into a laser printer toner cartridge to print common printing paper through a laser printer to obtain the super-hydrophobic coating. The nanoparticles having graphite oxide are not used as electron conductive material to make paper electron conductive and also an alcohol solvent is used.

Mohammad Shateri-Khalilabad, M Yazdanshenas, Preparation of superhydrophobic electroconductive graphene-coated cotton cellulose, Cellulose volume 20, pages 963-972 (2013), DOI: 10.1007/s10570-013-9873-y, discloses a method of making superhydrophobic electroconductive graphene-coated cotton fabric involving three key steps (FIG. 1) comprising coat cotton fibers with Graphene oxide (GO) by simple dip-pad-dry process, Reduce Graphene oxide (GO)-cotton with ascorbic acid to convert Graphene oxide (GO) into conductive graphene and a low surface energy PMS layer was formed on graphene-coated sample.

Mohammad Shateri-Khalilabad, M Yazdanshenas, Fabricating electroconductive cotton textiles using graphene, Carbohydrate Polymers, Volume 96, Issue 1, 1 Jul. 2013, Pages 190-195, discloses graphene-coated cotton fabric comprising graphene oxide (GO)-coated samples Prepared by immersing cotton fabric in aqueous solution of reducing agents of NaBH4, N2H4, C6H8O6, Na2S2O4 and NaOH and heat at 95 DEG C for 60 min under constant stirring. The resulting fabric was washed with large amount of water several times and samples were dried at 90 DEG C for 30 min to obtain graphene-coated cotton fabric.

Hongtao Zhao, Mingwei Tian, Yunna Hao, Lijun Qu, Shifeng Zhu, Shaojuan Chen, Fast and facile graphene oxide grafting on hydrophobic polyamide fabric via electrophoretic deposition route, Journal of Materials Science, volume 53, pages 9504-9520 (2018), discloses a fabrication process for polyamide/rGO composite fabric (FIG. 3) comprising polyamide fabric was pretreated by polyethylenimine (PEI) or cationic finishing agent (KH-560) to introduce positive charges on substrate for better interfacial affinity to anionic polyelectrolyte graphene oxide. The treated fabric was tightly wrapped on an anode electrode, and then homemade GO suspension dispersed with ultrasound was slowly poured into the EPD equipment, electrophoretic deposition was carried out under constant DC electric field after connected power supply, washed to remove redundant GO suspensions, followed by natural drying at room temperature and polyamide/rGO fabric was obtained through thermal reduction by hot press at 210 DEG C for 60 min.

### SUMMARY OF THE INVENTION

It is an object of the present invention to at least partly overcome the above-mentioned problems, and to provide an improved electron conducting coating.

This object is achieved by a coating as defined in claim 1.

According to an aspect of the invention, an electron conducting coating comprising or consisting of
I) a first coating prepared from a first composition comprising or consisting of
   2 to 15 wt % of a polymerized C₁₀₋₃₀alkanetriC₁₋₅alkoxysilane,
   0.3 to 1.5 wt % of a surfactant,
   0.04 to 0.40 wt % of an organic acid catalyst,
   optionally 0.5 to 10 wt % of an inorganic component selected from the group comprising or consisting of silica dioxide gel, pyrogenic silica, crystalline silica, titanium dioxide, and water glass (WGSi), and
   up to 100 wt % water, wherein weight percentages are percentages of the total weight of the first composition, and
II) a second coating prepared from a second composition comprising or consisting of 1 to 25 wt % of an electron conducting element selected from the group comprising or consisting of graphene, nanographite and an electron conducting polymer,
   optionally, 0.1 to 10 wt % of an additive/binder,
   optionally, 0.01 to 5 wt % of a dispersion agent, and
   up to 100 wt % water, wherein weight percentages are percentages of the total weight of the second composition.

The invention also relates to a method for preparing an electron conducting coating comprising or consisting of
Step a) preparing a first coating from a first composition by catalytic hyrophobization using the steps of
   a1) providing a solution of 0.3 to 1.5 wt % of surfactant and 0.04 to 0.40 wt % of an organic acid catalyst,
   a2) adding 3 to 15 wt % of a polymerized C₁₀₋₃₀alkanetriC₁₋₅alkoxysilane until polymerized and homogenized,
   a3) optionally providing 0.5 to 10 wt % of an inorganic component selected from the group comprising or consisting of silica dioxide gel, pyrogenic silica, crystalline silica, titanium dioxide, and water glass (WGSi),
   a4) adding the 0.5 to 10 wt % solution of step a3) to the polymerized C₁₀₋₃₀alkanetriC₁₋₅alkoxysilane, and
   a5) homogenizing the obtained mixture,
   wherein weight percentages are percentages of the total weight of the first composition,
   a6) applying the first composition on a surface, drying at room temperature or pressing the covered surface using a heated sheet at a temperature above 40° C., or above 60° C., or above 90° C. at a pressure of at least 50 kPa, or at least 60 kPa, or at least 90 kPa for 10 to 30 minutes, and
Step b) Coating said surface with a second composition comprising electron conductive material using the steps of
   b1) providing a second composition comprising or consisting of 1 to 25 wt % of an electron conducting element selected from the group comprising or consisting of graphene, nanographite and an electron conducting polymer,
   optionally, 0.1 to 10 wt % of an additive/binder,
   optionally, 0.01 to 5 wt % of a dispersion agent, and
   up to 100 wt % water, wherein weight percentages are percentages of the total weight of the second composition,
   b2) applying the second coating on the first coating, followed by drying.

In some aspects, homogenization is done at 6000 to 8000 rpm for 5 to 25 minutes.

In some aspects, the amounts of the ingredients are
5 to 13 wt % of a polymerized C₁₄₋₂₀alkanetrimethoxyalkoxysilane,
0.4 to 1.1 wt % of a surfactant,
0.05 to 0.30 wt % of an organic acid catalyst,
1 to 10 wt % of an electron conducting element,
optionally, 0 to 5 wt % of an additive/binder, and
optionally, 0.05 to 1 wt % of a dispersion agent.

In some aspects, the inorganic component is silica dioxide gel. In some aspects, the inorganic component is pyrogenic silica. In some aspects, the inorganic component is crystalline silica. In some aspects, the inorganic component is water glass (WGSi). In some aspects, the inorganic component is titanium dioxide.

In some aspects, the polymerized silane is C₁₄₋₂₀alkanetrimethoxysilane or hexadecyltrimethoxysilane or octadecyltrimethoxysilane.

In some aspects, the organic acid catalyst is selected from the group comprising or consisting of tartaric acid, citric acid, oxalic acid, fumaric acid, maleic acid and lactic acid and arylsulfonic acid. In some aspects, the organic acid catalyst is citric acid.

In some aspects, the surfactant is sodium dodecyl sulfate.

In some aspects, the electron conducting element is graphene. In some aspects, the electron conducting element is nanographite. In some aspects, the electron conducting polymer is selected from the group comprising or consisting of polypyrrole (PPy), polyaniline (PANI), polythiophene (PTh), poly (3,4-ethylenedioxythiophene) (PEDOT) and their derivatives.

In some aspects, the binder is selected from the group comprising or consisting of nanocellulose, microcrystalline cellulose, CNF, MFC, CNC, NFC, PVA and PVDF. In some aspects, the binder is TEMPO-oxidized kraft-pulp NFC.

In some aspects, the dispersion agent is selected from the group comprising or consisting of polyacrylic acid, poly-vinyl alcohol, biopolymers, such as lignosulfonic acid, starch, etc. In some aspects, the dispersion agent is polyacrylic acid.

In some aspects, graphene as ingredient in the first coating is disclaimed. In some aspects, cellulose as ingredient in the first coating is disclaimed. In some aspects, surface modified silica as ingredient is disclaimed. In some aspects, silanized silica as ingredient in the first coating is disclaimed. In some aspects, the inorganic component in the first coating is silicon is disclaimed. In some aspects, the inorganic component in the first coating is pyrogenic silica, is disclaimed. In some aspects, the inorganic component in the first coating is crystalline silica, is disclaimed. In some aspects, silanized cellulose as ingredient in the first coating is disclaimed. In some aspects, sulfonate as an ingredient in the first coating is disclaimed. In some aspects, ammonium as ingredient in the first coating is disclaimed.

The invention further relates to a use of the coating as defined anywhere herein for coating organic and inorganic surfaces. The surfaces may be animated or non-animated. In some aspects, the surfaces are selected from the group comprising or consisting of plastics, glass, polyester, silk, fabrics, metals surface, textile, cellulose, cotton, paper sheets, cardboard, CTMP-film, polysaccharide films, cellulose-films, thermomechanical pulps film, bleach sulphite pulp sheet, filter paper, nanocellulose films and wood.

### BRIEF DESCRIPTION OF THE DRAWINGS

The invention will now be explained more closely by the description of different embodiments of the invention and with reference to the appended figures.

FIG. 1 shows pictures of treated and untreated paper.

FIG. 2 shows pictures of treated and untreated paper.

FIG. 3 shows a constant current graph from the different samples of AHSP paper.

FIG. 4 shows a constant current graph from the different samples of Exopress paper.

FIG. 5 shows a cyclic voltametric graph from the different samples of AHSP paper.

FIG. 6 shows a cyclic voltametric graph from the different samples of Exopress paper.

FIG. 7 shows a Roll-to-Roll coating problematics with high water content formulation and paper substrates using the costing of the invention.

FIG. 8 shows a Roll-to-Roll coating problematics with high water content formulation and paper substrates using only the first coating.

FIG. 9 shows a coated electrode on pretreated Exopress 72 (a-d) and AHSP (e-h) after drying 24 hours at room temperature.

### DETAILED DESCRIPTION OF VARIOUS EMBODIMENTS OF THE INVENTION

### Definitions and Abbreviations

polyvinylidene difluoride (PVDF)
Poly(vinyl alcohol) (PVOH, PVA, or PVAI)
cellulose nanofibrils (CNF)
computer numerical control (CNC)
microfibrillated cellulose (MFC)
Nanofibrillated cellulose (NFC)

The definitions set forth in this application are intended to clarify terms used throughout this application. The term “herein” means the entire application.

As used herein, the term “wt %” and “% w/w” means percentages of the total weight of the composition.

As used herein, the term “optional” or “optionally” means that the subsequently described event or circumstance may but need not occur, and that the description includes instances where the event or circumstance occurs and instances where it does not.

As used herein, the terms “Cn”, used alone or as a suffix or prefix, is intended to include hydrocarbon-containing groups; n is an integer from 1 to 40.

The expression “from xx to yy” and “of xx to yy” means an interval from or of, and including xx, to and including yy. For example, from 2 to 4 includes numbers 2.0 and 4.0 and any number in between 2.0 and 4.0.

As used herein the term “C₁₀₋₃₀alkane” used alone or as a suffix or prefix, is intended to include both saturated or unsaturated, branched or straight chain, monovalent hydrocarbon radical derived by the removal of one hydrogen atom from a single carbon atom or atom or a parent alkane, alkene or alkyne. Examples include, but are not limited to, decanyl, undecane, dodecane, tridecane, tetradecane, pentadecane, hexadecane, heptadecane, octadecane, nonadecane, icosane, henicosane, docosane, tricosane, tetracosane, pentacosane, hexacosane, heptacosane, octacosane, nonacosane, triacontane, and any stereoisomer of any of these alkanes. The term “alkyl” is specifically intended to include groups having any degree or level of saturation, including groups having exclusively single carbon-carbon bonds, groups having one or more double carbon-carbon bonds, groups having one or more triple carbon-carbon bonds, and groups having combinations of single, double, and triple carbon-carbon bonds.

As used herein, the term “alkoxy” or C₁₋₃-alkoxy “, used alone or as a suffix and prefix, refers to an alkyl radical which is attached to the remainder of the molecule through an oxygen atom. Examples of C₁₋₅-alkoxy include methoxy, ethoxy, propoxy, butoxy and pentoxy. Examples of C₁₋₃-alkoxy include methoxy, ethoxy, n-propoxy and isopropoxy.

As used herein, “polymer” refers to a chemical species or a radical made up of repeatedly linked moieties. The number of repeatedly linked moieties is 10 or higher. The linked moieties may be identical or may be a variation of moiety structures.

As used herein, the term “room temperature” means a temperature from 16 to 25° C.

The first composition comprises or consists of a polymerized C₁₀₋₃₀alkanetriC₁₋₅alkoxysilane, a surfactant, an organic acid catalyst and water, and optionally an inorganic component.

The polymerized C₁₀₋₃₀alkanetriC₁₋₅alkoxysilane may be C₁₄₋₂₀alkanetriC₁₋₃alkoxysilane or C₁₄₋₂₄alkanetrimethoxysilane. The polymerized C₁₀₋₃₀alkanetriC₁₋₅alkoxysilane may be C₁₄₋₂₀alkanetrimethoxysilane or hexadecyltrimethoxysilane or octadecyltrimethoxysilane.

The amount of silane used may be from 2 to 15 wt %, or 3 to 6 wt %, or from 4 to 5 wt %, or from 4.5 to 5 wt %, when an inorganic component is present in the first composition. The amount of silane used may be from 3 to 10 wt %, or from 4 to 9 wt %, when an inorganic component is present in the first composition. When no inorganic compound is present in the first composition, the amount of silane may be from 5 to 15 wt %, or 6 to 13 wt %.

The surfactant may be any surfactant known in the art. The surfactant may be sodium dodecyl sulfate.

The amount of surfactant use may be from 0.6 to 0.9 wt %, or from 0.7 to 0.85 wt %, when an inorganic component is present in the first composition. The amount of surfactant use may be from 0.5 to 1 wt %, when no inorganic component is present in the first composition.

The organic acid catalyst may be citric acid. The organic acid catalyst may be tartaric acid. The organic acid catalyst may be oxalic acid. The organic acid catalyst may be arylsulfonic acid. The organic acid catalyst may be selected from the group comprising or consisting of fumaric acid, maleic acid and lactic acid.

The amount of organic acid catalyst use may be from 0.01 to 0.5 wt %, or 0.02 to 0.3 wt %, or 0.03 to 0.09 wt %, or from 0.04 to 0.08 wt %, or from 0.045 to 0.07 wt %. The amount of organic acid catalyst use may be from 0.01 to 0.3 wt %, %, or from 0.05 to 0.28 wt %, when no inorganic component is present in the first composition. The amount of organic acid catalyst use may be from 0.02 to 0.2 wt %, or from 0.05 to 0.15 wt %, when an inorganic component is present in the first composition.

The inorganic component may be selected from the group comprising silica dioxide gel, pyrogenic silica, crystalline silica, titanium dioxide and water glass (WGSi). The inorganic component may be silica dioxide gel. The inorganic component may be titanium dioxide. The inorganic component may be water glass (WGSi). The inorganic component may be pyrogenic silica. The inorganic component may be crystalline silica.

The amount of inorganic component use may be from 0.5 to 10 wt %, or 3 to 10 wt %, or 0.5 to 5.5 wt %, 1 to 4 wt %, or 4 to 5 wt %, or 0.5 to 3.5 wt % or 2 to 3 wt %, or 1.5 to 3.5 wt %, or 2.1 to 2.9 wt %. The amount of inorganic component may vary depending on the application of the coating. For fire resistance for example, the coating may comprise 5 to 10 wt % of an inorganic component, such as silica dioxide.

The first composition may comprise or consist of
4 to 10 wt % of polymerized C₁₀₋₃₀alkanetri C₁₋₅alkoxysilane,
0.6 to 0.9 wt % of surfactant,
0.04 to 0.2 wt % or 0.04 to 0.08 wt % of organic catalyst,
0.5 to 5 wt % of an inorganic component selected from the group comprising or consisting of silica dioxide gel, pyrogenic silica, crystalline silica, and titanium dioxide, and
up to 100 wt % water.

The surfactant may be sodium dodecyl sulfate. The organic acid catalyst may be selected from the group comprising or consisting of tartaric acid, citric acid, oxalic acid, fumaric acid, maleic acid and lactic acid and arylsulfonic acid. The polymerized alkanetrialkoxysilane may be hexadecyltrimethoxysilane or octadecyltrimethoxysilane.

The invention relates to a coating comprising or consisting of any combination of ingredients mentioned herein.

In the tables below, none limiting examples of combinations are exemplified, wherein the polymerized silane is hexadecyltrimethoxysilane or octadecyltrimethoxysilane, the surfactant is sodium dodecyl sulfate and the electron conducting element is graphene or nanographite.

The amounts of the ingredients are as defined anywhere herein, such as the amounts defined in claim 1 or 3.

| | silica | | | | water | |
|---|---|---|---|---|---|---|
| | dioxide | pyrogenic | crystalline | titanium | glass | |
| | gel | silica | silica | dioxide | (WGSi) | |
| citric acid | x | x | x | x | x | nanocellulose |
| oxalic acid | x | x | x | x | x | CNF |
| fumaric | x | x | x | x | x | MFC |
| acid | | | | | | |
| maleic acid | x | x | x | x | x | CNC |
| lactic acid | x | x | x | x | x | PVA |
| arylsulfonic | x | x | x | x | x | PVDF |
| acid | | | | | | |

| | citric | oxalic | fumaric | maleic | lactic | arylsulfonic | |
|---|---|---|---|---|---|---|---|
| | acid | acid | acid | acid | acid | acid | |
| silica | x | x | x | x | x | x | nanocellulose |
| dioxide | | | | | | | |
| gel | | | | | | | |
| pyrogenic | x | x | x | x | x | x | CNF |
| silica | | | | | | | |
| crystalline | x | x | x | x | x | x | MFC |
| silica | | | | | | | |
| titanium | x | x | x | x | x | X | CNC |
| dioxide | | | | | | | |
| water | x | x | x | x | x | x | PVA |
| glass | | | | | | | |
| (WGSi) | | | | | | | |
| | x | x | x | x | x | x | PVDF |

| | | microcrystalline | | | | | | |
|---|---|---|---|---|---|---|---|---|
| | nanocellulose | cellulose | CNF | MFC | CNC | PVA | PVDF | |
| citric acid | x | x | x | x | x | x | x | silica |
| | | | | | | | | dioxide |
| | | | | | | | | gel |
| oxalic acid | x | x | x | x | x | x | x | pyrogenic |
| | | | | | | | | silica |
| fumaric | x | x | x | x | x | x | x | crystalline |
| acid | | | | | | | | silica |
| maleic | x | x | x | x | x | x | x | titanium |
| acid | | | | | | | | dioxide |
| lactic acid | x | x | x | x | x | x | x | water |
| | | | | | | | | glass |
| | | | | | | | | (WGSi) |
| arylsulfonic | x | x | x | x | x | x | x | |
| acid | | | | | | | | |

### Manufacturing

The invention also relates to a method for preparing of the first coating as defined anywhere herein comprising or consisting of the step of
a) providing the solution of 0.5 to 1.5 wt % or 0.6 to 0.9 wt % of surfactant and 0.04 to 0.5 wt %, or 0.05 to 0.3 wt %, or 0.04 to 0.08 wt % of an organic acid catalyst,
b) adding 5 to 15 wt %, or 6 to 12.5 wt %, or 2 to 5 wt %, or 4 to 5 wt % of C₁₀₋₃₀alkanetriC₁₋₅alkoxysilane until polymerized and homogenized
c) optionally, providing 0.5 to 10% wt or 2 to 5% wt solution of the inorganic component,
d) optionally adding the solution of the inorganic component to the polymerized C₁₀₋₃₀alkanetriC₁₋₅alkoxysilane, and
e) homogenizing the obtained mixture, wherein weight percentages are percentages of the total weight of the first composition.

The process for the manufacturing of the first coating as defined anywhere herein may comprise or consist of the step of
a) providing the solution of 0.4 to 1.5 wt % of surfactant and 0.04 to 0.3 wt % of tartaric acid, citric acid or oxalic acid, or fumaric acid, maleic acid and lactic acid,
b) adding 3 to 15 wt % of C₁₆₋₁₈alkanetriC₁₋₃alkoxysilane until polymerized and homogenized,
c) providing 0.5 to 10 wt % solution of inorganic component selected from the group comprising or consisting of silica dioxide gel (e.g. 2.4 wt % of total first composition), pyrogenic silica (e.g. 2.4 wt % of total first composition), crystalline silica (e.g. 2.4 wt % of total first composition), titanium dioxide (e.g. 2.4 wt % of total first composition), nanographite water glass (WGSi) (e.g. 2.4 wt % of total first composition), or titanium oxide (e.g. 4.6 wt % of total first composition),
d) adding the 0.5 to 10 wt % solution of step c) to the polymerized C₁₆₋₁₈alkanetriC₁₋₃alkoxysilane, and
e) homogenizing the obtained mixture, wherein weight percentages are percentages of the total weight of the first composition.

The surfactant may be sodium dodecyl sulfate. The organic acid catalyst may be selected from the group comprising or consisting of tartaric acid, citric acid, oxalic acid, fumaric acid, maleic acid and lactic acid and arylsulfonic acid. The organic acid catalyst may be citric acid. The polymerized alkanetrialkoxysilane may be hexadecyltrimethoxysilane or octadecyltrimethoxysilane. The inorganic component may be selected from the group comprising or consisting of silica dioxide gel, pyrogenic silica and titanium dioxide or water glass (WGSi).

The method for preparing of the first coating as defined anywhere herein may comprise or consist of the step of
a) providing the solution of 0.6 to 0.9 wt % of surfactant and 0.04 to 0.08 wt % of citric acid,
b) adding 4 to 5 wt % of C₁₆₋₁₈alkanetriC₁₋₃alkoxysilane until polymerized and homogenized,
c) providing 0.5 to 10 wt % solution of silica dioxide gel (e.g. 2.4 wt % of total first composition), pyrogenic silica (e.g. 2.4 wt % of total first composition), crystalline silica (e.g. 2.4 wt % of total first composition), titanium dioxide (e.g. 2.4 wt % of total first composition), nanographite water glass (WGSi) (e.g. 2.4 wt % of total first composition), or titanium oxide (e.g. 4.6 wt % of total first composition),
d) adding the 0.5 to 10 wt % solution of step c) to the polymerized C₁₆₋₁₈alkanetriC₁₋₃alkoxysilane, and
e) homogenizing the obtained mixture, wherein weight percentages are percentages of the total weight of the first composition.

### Use

The first and second composition as defined anywhere herein may be applied to a surface using a brush or by pencilling the first composition on a surface. Alternatively, the first and second composition may be sprayed on a surface. The first and second composition may also be applied on a surface using a frame, such as a standard Zehnter application frame.

The first composition may be applied on a surface using hot pressing. A method for applying the first composition on a surface may comprise or consist of the step of
applying the first coating on a surface, pressing the covered surface using a heated sheet at a temperature above 40° C., or above 60° C., or above 90° C. at a pressure of at least 50 kPa, or at least 60 kPa, or at least 90 kPa for 10 to 30 minutes. The method for applying the first composition on a surface may for example comprise or consist of the step of
applying the first composition on a surface, pressing the surface using a heated sheet at a temperature above 90° C., or between 9° and 100° C. at a pressure of at least 95 kPa, or between 90 and 100 kPa, for 15 to 25 minutes.

The method is simple, inexpensive, quick and scalable.

The surfaces may be made of organic or inorganic material, or mixtures thereof. The surface may be a fabric, cotton, textile, polyester, silk and glass. Other examples of surfaces are metal, plastics and wood materials.

Examples of paper that may be used are Chemomechnical pulp, Bleash sulphite pulp, nanopaper, CNC-film, paper board, thermomechanical

### Experiment

### Material and Method

Citric acid, Tartaric acid, Oxalic acid, Hexadecyl trimethoxy silane (85%), Octadecyl trimethoxy silane (90%), Silica gel high grade (w/Ca, about 0.1%), pore size 60 Å, 230-400 mesh particle size, Sodium silicate solution (25-28%), TiO₂, Sigma Aldrich. pyrogenic silica, Wacker.

Sodium dodecyl sulphate (SDS), VWR chemicals.

Silica particles were prepared from Sodium silicate solution (25-28%) in the lab.

Emulsion homogenizing was made using an ULTRA TURRAX mixer (IKA T 25 digital).

Drying of samples was done in Rapid Köthen (RK) sheet former at 93° C. at an applied pressure of 96 kPa for 20 minutes.

The water contact angle was recorded on PGX+ contact angle analyzer-Pocket Goniometer.

### Emulsions Preparation as a Water Based Hydrophobic Material

### Polymerization of Silanes

In a 250 ml round-bottom flask, sodium dodecyl sulphate (1.15 g, 4 mmol) was dissolved in distilled water (100 ml) by stirring slowly for 30 minutes at room temperature. Then, citric acid (100 mg, 0.52 mmol) was added to the mixture and followed by stirring for 5 minutes, the temperature was fixed at 40° C. and hexadecyl trimethoxy silane (85%, 8 ml, 17.5 mmol) was added dropwise and stirred for 5 minutes. Then the reaction continued at 40° C. in static condition for 48 hours. After that, the mixture was homogenized using an ULTRA TURRAX mixer (IKA T 25 digital) at 6000 rpm for 5 minutes.

Preparing Silica Particles from Sodium Silicate Solution (Water Glass)

Citric acid (1 M, 4 ml) was added slowly in a sodium silicate solution (25-28%, 10 g) at room temperature. The silica particles precipitated. Distilled water (5 0 ml) was added, and pH was fixed by adding HCl (2 M) at 6-6.5 and washed using distilled water until the NaCl salt was removed totally. The supernatant was checked by AgNO₃ solution (1 M). The mixture was diluted with distilled water to 10% of silica particles suspension and homogenized using ULTRA TURRAX mixer (IKA T 25 digital) at 7000 rpm for 10 minutes. These particles are herein referred to as WGSi.

### Preparation of the First Compositions

Inorganic particles (SiO₂, WGSi, TiO₂ or nanographite) suspension was added to the polymerized silane and homogenized at 6000 rpm for 1 minute.

### EXAMPLE 1

2.3 g SDS (0.78% w/w), 0.2 g citric acid (0.068% w/w), 13.8 g hexadecyltrimethoxy silane (4.6% w/w), 7.2 g silica gel (2.4% w/w), 200 g water (polymerization step), 72 g water with 10% w/w suspending inorganic component, total water (92% w/w). (Total amount emulsified liquid first composition=295 g), final pH=3.2.

### EXAMPLE 2

2.3 g SDS (0.78% w/w), 0.15 g tartaric acid (0.05% w/w), 13.8 g hexadecyltrimethoxy silane (4.6% w/w), 7.2 g silica gel (2.4% w/w), 200 g water (polymerization step), 72 g water with 10% w/w suspending inorganic component, total water (92% w/w). (Total amount emulsified liquid first composition=295 g), final pH=3.4.

### EXAMPLE 3

2.3 g SDS (0.78% w/w), 0.1 g oxalic acid (0.05% w/w), 13.8 g hexadecyltrimethoxy silane (4.6% w/w), 7.2 g silica gel (2.4% w/w), 200 g water (polymerization step), 72 g water with 10% w/w suspending inorganic component, total water (92% w/w). (Total amount emulsified liquid first composition=295 g), final pH=2.8.

### EXAMPLE 4

2.3 g SDS (0.78% w/w), 0.2 g citric acid (0.068% w/w), 15 g octadecyltrimethoxy silane (5% w/w), 7.2 g silica gel (2.4% w/w), 200 g water (polymerization step), 72 g water with 10% w/w suspending inorganic component, total water (92% w/w). (Total amount emulsified liquid first composition=296 g), final pH=3.2.

### EXAMPLE 5

2.3 g SDS (0.78% w/w), 0.2 g citric acid (0.068% w/w), 13.8 g hexadecyltrimethoxy silane (4.6% w/w), 7.2 g WGSi (SiO₂2.4% w/w), 200 g water (polymerization step), 72 g water with 10% w/w suspending inorganic component, total water (92% w/w). (Total amount emulsified liquid first composition=295 g), final pH=9.5.

### EXAMPLE 6

2.3 g SDS (0.76% w/w), 0.2 g citric acid (0.066% w/w), 13.8 g hexadecyltrimethoxy silane (4.5% w/w), 14.4 g TiO₂ (4.6% w/w), 200 g water (polymerization step), 72 g water with 20 % w/w suspending inorganic component, total water (90% w/w). (Total amount emulsified liquid first composition=302 g), final pH=3.2.

### EXAMPLE 7

2.3 g SDS (0.78% w/w), 0.2 g citric acid (0.068% w/w), 13.8 g hexadecyltrimethoxy silane (4.6% w/w), 7.2 g nanographite (2.4% w/w), 200 g water (polymerization step), 72 g water (suspending inorganic component), total water (92% w/w). (Total amount emulsified liquid first composition=295 g), final pH=3.2.

### EXAMPLE 8

2.3 g SDS (0.78% w/w), 0.2 g citric acid (0.068% w/w), 13.8 g hexadecyltrimethoxy silane (4.6% w/w), 7.2 g pyrogenic silica (2.4% w/w), 200 g water (polymerization step), 72 g water with 10% w/w suspending inorganic component, total water (92% w/w). (Total amount emulsified liquid first composition=295 g), final pH=3.0.

### Applying the Water-Based Formula on the Surface

The first composition was applied on the surface by coating or spraying. The modified surface was left at room temperature until the materials were adsorbed by the surface. This time varies between 20-30 minutes depending on the first composition and surface. A surface area of 20 cm² was covered with 0.74-0.76-gram material by penciling and 0.64-0.66 gram using spray. For the reaction between the chemicals and surface either Rapid-köthen (RK) sheet former or Rotopress were used. Rapid-köthen sheet former was used at 93° C. at an applied pressure of 96 kPa for 20 minutes, and the Rotopress was used at 260° C., at a pressure of 8 MPa, with a speed of 3 m/min.

TABLE 1
applying the suspension on diverse surfaces.

| | | | covering the | | |
|---|---|---|---|---|---|
| Entry ^{a} | Suspension | particles | surface | surface | Contact Angel ^{b} |
| 1 | EX 1, pH: 3.2 | SiO₂ from | Coating | CNC-coated paper | 145 |
| | | silica gel | | CTMP | 147 |
| | | | | Wood | 147 |
| 2 | EX 2, pH: 3.4 | SiO₂ from | Coating | CNC-coated paper | 140 |
| | | silica gel | | CTMP | 148 |
| 3 | EX 3, pH: 2.8 | SiO₂ from | Coating | CNC-coated paper | 139 |
| | | silica gel | | CTMP | 147 |
| 4 | EX 4, pH: 3.2 | SiO₂ from | Coating | CNC-coated paper | 147 |
| | | silica gel | | CTMP | 144 |
| | | | | Wood | 145 |
| 5 | Ex 5, pH: 9.5 | WGSi | Coating | CNC-coated paper | 149 |
| | | | | CTMP | 150 |
| | | | | Wood | 148 |
| 6 | Ex 5, pH: 9.5 | WGSi | Spray | CNC-coated paper | 147 |
| | | | | Cotton | 144 |
| | | | | Silk | 144 |
| | | | | Silk ^{c} | 144 |
| | | | | CNC film - rough surface | 147 |
| | | | | CNC film - smooth surface | 141 |
| | | | | wood | 144 |
| 7 | Ex 6, pH: 3.2 | TiO₂ | Coating | CNC-coated paper | 146 |
| | | | | CTMP | 142 |
| 8 | Ex 7, pH: 3.2 | Nanographite | Coating | CNC-coated paper | 143 |
| 9 | Ex 7, pH: 3.2 | Nanographite | Spray | CTMP | 142 |
| | | | | Filter paper | 134 |
| | | | | Glass ^{d} | 140 |
| 10 | EX 8, pH: 3.0 | Pyrogenic silica | Spray | CNC-coated paper | 153 |
| | | | | Filter paper | 156 |
| | | | | CTMP | 158 |
| | | | | Silk | 157 |
| | | | | wood | 154 |
| 11^{e} | Ex 5, pH: 9.5 | WGSi | Spray | CNC-coated paper | 130 |
| | | | Coating | CNC-coated paper | 130 |

^{a} The surface was covered by the first composition using a dipp coating, brushing or spray and dried by RK sheet former at 93° C. for 20 minutes.
^{b} Mean value of three measurements.
^{c} The modified silk was washed at 45° C. for 90 minutes, then a contact angel was measured.
^{d} The surface was dried after first spray and second spray was applied to cover the surface properly
^{e}The size of samples were A4 and for drying, Rotopress was used at 260° C., at a pressure of 8 MPa, and at a speed of 3 m/min.
CTMP = chemi-thermomechanical pulp
CNC = Cellulose Nanocrystals

### EXAMPLE 9

### Polymerization of Silanes

In a 250 ml round-bottom flask, flushed with milli-Q water (200 ml), sodium dodecyl sulphate (2.3 g, 8 mmol) was added and stirred slowly for 30 minutes at room temperature. Then, citric acid (200 mg, 1 mmol) was added to the mixture and followed by stirring for 5 minutes, and hexadecyl trimethoxy silane (85%, 14 g) was added slowly and stirred for 5 minutes. Afterwards, the reaction continued at 40° C. in static condition for 2 hours. Then, the mixture was kept at room temperature (i.e. of 16 to 28° C.) for an additional 46 hours. the prepared suspension was mixed at room temperature for 1 hour at 1400 rpm.

Entry 12.3 g SDS (1% w/w), 0.2 g citric acid (0.09% w/w), 14 g hexadecyltrimethoxy silane (6.5% w/w), 200 g water, final pH=3.0.

Entry 22.3 g SDS (1% w/w), 0.3 g citric acid (0.14% w/w), 14 g hexadecyltrimethoxy silane (6.5% w/w), 200 g water, final pH=2.9.

Entry 32.3 SDS (1% w/w), 0.4 g citric acid (0.18% w/w), 14 g hexadecyltrimethoxy silane (6.5% w/w), 200 g water, final pH=2.8.

Entry 42.3 g SDS (1% w/w), 0.6 g citric acid (0.27% w/w), 14 g hexadecyltrimethoxy silane (6.5% w/w), 200 g water, final pH=2.7.

Entry 52.3 g SDS (1% w/w), 0.28 g tartaric acid (0.14% w/w), 14 g hexadecyltrimethoxy silane (6.5% w/w), 200 g water, final pH=2.8.

Entry 6 2.3 g SDS (1% w/w), 0.4 g citric acid (0.18% w/w), 14.5 g octadecyltrimethoxy silane (6.7% w/w), 200 g water, final pH=2.8.

Entry 72.3 g SDS (1% w/w), 0.4 g citric acid (0.17% w/w), 28 g hexadecyltrimethoxy silane (12% w/w), 200 g water, final pH=2.8.

Entry 82.3 g SDS (1% w/w), 0.4 g citric acid (0.17% w/w), 29 g octadecyltrimethoxy silane (12.4% w/w), 200 g water, final pH=2.8.

Entry 92.3 g SDS (0.78% w/w), 0.4 g citric acid (0.14% w/w), 14 g hexadecyltrimethoxy silane (4.6% w/w), 7.2 g pyrogenic silica (2.4% w/w), 200 g water (polymerization step), 72 g water with 10% w/w suspending inorganic component, total water (92% w/w), final pH=3.0.

Entry 10 2.3 g SDS (0.74% w/w), 0.4 g citric acid (0.13% w/w), 28 g hexadecyltrimethoxy silane (9% w/w), 7.2 g pyrogenic silica (2.3% w/w), 200 g water (polymerization step), 72 g water with 10% w/w suspending inorganic component, total water (87% w/w), final pH=3.1.

Entry 11 2.3 g SDS (0.78% w/w), 0.2 g citric acid (0.07% w/w), 14 g hexadecyltrimethoxy silane (4.6% w/w), 7.2 g nanographite (2.4% w/w), 200 g water (polymerization step), 72 g water with 10% w/w suspending inorganic component, total water (92% w/w), final pH=3.0.

Entry 12 2.3 g SDS (1% w/w), 0.22 g fumaric acid (0.1% w/w), 28 g hexadecyltrimethoxy silane (12% w/w), 200 g water, final pH=2.8.

Entry 13 2.3 g SDS (1% w/w), 0.17 g lactic acid (0.07% w/w), 28 g hexadecyltrimethoxy silane (12% w/w), 200 g water, final pH=3.0.

Entry 14 2.3 g SDS (1% w/w), 0.22 g maleic acid acid (0.1% w/w), 28 g hexadecyltrimethoxy silane (12% w/w), 200 g water, final pH=2.4.

Entry 15 1.15 g SDS (0.5% w/w), 0.4 g citric acid (0.17% w/w), 29 g octadecyltrimethoxy silane (12.4% w/w), 200 g water, final pH=2.8.

Entry 16 1.15 g SDS (0.5% w/w), 0.4 g citric acid (0.17% w/w), 28 g hexadecyltrimethoxy silane (12% w/w), 200 g water, final pH=2.8.

Entry 17 2.3 g SDS (0.78% w/w), 0.22 g fumaric acid (0.07% w/w), 14 g hexadecyltrimethoxy silane (4.6% w/w), 7.2 g pyrogenic silica (2.4% w/w), 200 g water (polymerization step), 72 g water with 10% w/w suspending inorganic component, total water (92% w/w), final pH=2.8.

Entry 18 2.3 g SDS (0.78% w/w), 0.17 g lactic acid (0.06% w/w), 14 g hexadecyltrimethoxy silane (4.6% w/w), 7.2 g pyrogenic silica (2.4% w/w), 200 g water (polymerization step), 72 g water with 10% w/w suspending inorganic component, total water (92% w/w), final pH=3.0.

Entry 19 2.3 g SDS (0.78% w/w), 0.22 g maleic acid (0.07% w/w), 14 g hexadecyltrimethoxy silane (4.6% w/w), 7.2 g pyrogenic silica (2.4% w/w), 200 g water (polymerization step), 72 g water with 10% w/w suspending inorganic component, total water (92% w/w), final pH=2.5.

Entry 20 2.3 g Brij® C10 (1% w/w), 0.4 g citric acid (0.17% w/w), 28 g hexadecyltrimethoxy silane (12% w/w), 200 g water, final pH=2.7.

Entry 21 2.3 g Berol 02 (1% w/w), 0.4 g citric acid (0.17% w/w), 28 g hexadecyltrimethoxy silane (12% w/w), 200 g water, final pH=2.6.

TABLE 2
applying the suspension on diverse surfaces.

| Entry ^{a} | Suspension | Inorganic particles | Substrate | Contact Angel ^{b} |
|---|---|---|---|---|
| 1 | EX 1, pH: 3.0 | — | Filter Paper | 120 |
| 2 | EX 2, pH: 2.9 | — | Filter Paper | 120 |
| 3 | EX 3, pH: 2.8 | — | Filter Paper | 133 |
| 4 | EX 4, pH: 2.7 | — | Filter Paper | 133 |
| 5 | Ex 5, pH: 2.8 | — | CNC film | 144 |
| 6 | Ex 6, pH: 2.8 | — | Filter Paper | 140 |
| 7 | Ex 7, pH: 2.8 | — | Filter Paper | 150 |
| | | | CNC film | 152 |
| 8 | Ex 8, pH: 2.8 | — | Filter Paper | 149 |
| | | | CNC film | 152 |
| 9 | Ex 9, pH: 3.0 | Pyrogenic silica | Filter paper | 157 |
| | | | Paper (kraft liner 170 g/m²) | 152 |
| 10 | EX 10, pH: 3.1 | Pyrogenic silica | Filter paper | 152 |
| 11 | EX 11, pH: 3.0 | nanographite | Paper (Exopress 72, 49 g/m²) | 140 |
| 12 | EX 12, pH: 2.8 | — | Filter Paper | 133 |
| 13 | EX 13, pH: 3.0 | — | Filter Paper | 140 |
| 14 | EX 14, pH: 2.4 | — | Filter Paper | 132 |
| 15 | EX 15, pH: 2.8 | — | Filter Paper | 142 |
| 16 | EX 16, pH: 2.8 | — | Filter Paper | 134 |
| 17 | EX 17, pH: 2.8 | Pyrogenic silica | Filter paper | 150 |
| 18 | EX 18, pH: 3.0 | Pyrogenic silica | Filter paper | 157 |
| 19 | EX 19, pH: 2.5 | Pyrogenic silica | Filter paper | 157 |
| 20 | EX 20, pH: 2.7 | — | Filter paper | 0.00 |
| 21 | EX 21, pH: 2.6 | — | Filter paper | 0.00 |
| 22 | Commercial OrganoTex | | Filter paper | 125 |
| | pH: 4.7 | | | |

^{a} The surface of substrates were treated by suspension using spray, and the RK sheet former was used to complete the reaction at 93° C. for 20 minutes.
^{b} Mean value of three measurements.

### EXAMPLE 10

A method for preparation of the coating of the invention
Step 1: Catalytic Hyrophobization with Aqueous Formulation
Polymerization of silanes
   In a flask we add 1,150 g of sodium dodecyl sulfate (SDS) then we add 100 ml of water. It is stirred until total dissolution of SDS (around 30 min), then we add the citric acid, we keep stirring, we start to heat the solution at 40° C., and after 5 minutes we add slowly hexadecyltrimethoxysilane (C₁₆—Si), after 2 min the stirring is stopped while maintaining the heating at 40° C. for 2 hours. The heating is stopped, and the mixture is left for 46 hours.
   Then after 46 hours the mixture is stirred 30 min at 1500 rpm, the table 3 shows the different quantities used for each formulation.

TABLE 3
Different quantities used for each formulation

| Name | C₁₆—Si | Citric acid | SDS | Water |
|---|---|---|---|---|
| ZD-01 | 16 mL/14.24 g | 200 mg | 1,150 g | 100 mL |
| ZD-02 | 8 mL/7.12 g | 100 mg | 1,150 g | 100 mL |
| ZD-03 | 6 mL/5.34 g | 75 mg | 1,150 g | 100 mL |
| Df-01 | 8 mL/7.12 g | 200 mg | 1,150 g | 100 mL |

The aqueous formulation was prepared according to the patent application PCT/EP2021/087037, Cordova, A. and Alimohammadzadeh,
Coating with the water-based composition to prepare hydrophobic substrates.
   The composition was applied on the surface using a spraying method.
   The modified surface was left at room temperature until the materials was adsorbed by the surface, this time varies between 10-20 minutes depending on the substrate.
   For the reaction between the chemicals and surface, Rapid-köthen sheet former was used at 93° C. at an applied pressure of 96 kPa for 20 minutes.
   The surface was covered with hydrophobic material with 2-13 gram/m² depending on the different formulation and different substrates.
      Step 2: Coating with Formulation Including Electron Conductive Material (e.g Graphene, Nanographite or an Electron Conducting Polymer)
The formulation composition was 95.2% water, 4.3%, nanographite, 0.4% TEMPO-oxidized kraft-pulp NFC and 0.1% poly-acrylic acid.
   The nanographite was produced according to Blomquist, N., Alimadadi, M., Hummelgård, M., Dahlström, C., Olsen, M., & Olin, H. (2019). Effects of geometry on large-scale tube-shear exfoliation of graphite to multilayer graphene and nanographite in water. Scientific reports, 9(1), 1-8, with the S1 shear zone
Two different paper substrates were used, pre-coated in step 1, one machine finished uncoated mechanical paper (EXOPRESS 72) and one high strength sack kraft paper (AHSP)
The formulation with electron conductive material was coated onto the pre-coated paper substrate using a standard Zehnter application frame with 250 μm wet coating thickness.
The coated samples were let to dry in room temperature for 24 h.
After drying sheet, resistance measurements were performed followed by assembly and electrochemical measurements of standard symmetrical Electric Double layer capacitor (EDLC) coin cells (CR2032). Galvanostatic cycling at constant current and cyclic voltammetry was performed on each sample. to determine the electrochemical properties and to determine if the step 1 coating allows electrolyte ion transport through the substrate, which is needed in electrical energy storage applications.

AHSP sample DF-01 and ZD-03 showed a significant improvement in coating with very low number of wrinkles. All samples made on AHSP-substrate shows unchanged or increased performance in the supercapacitor cells compared to the reference (AHSP without pre-coating, i.e. without coating with the first coating)

Exopress sample ZD-3 showed a significant improvement in coating with very low number of wrinkles. Sample ZD-03 and DF-01 on AHSP shows increased performance in the EDLC cells while RA-127 (ZD-02) showed significantly lower performance compared to the reference (EXOPRESS 72 without pre-coating, i.e. without coating with the first coating)

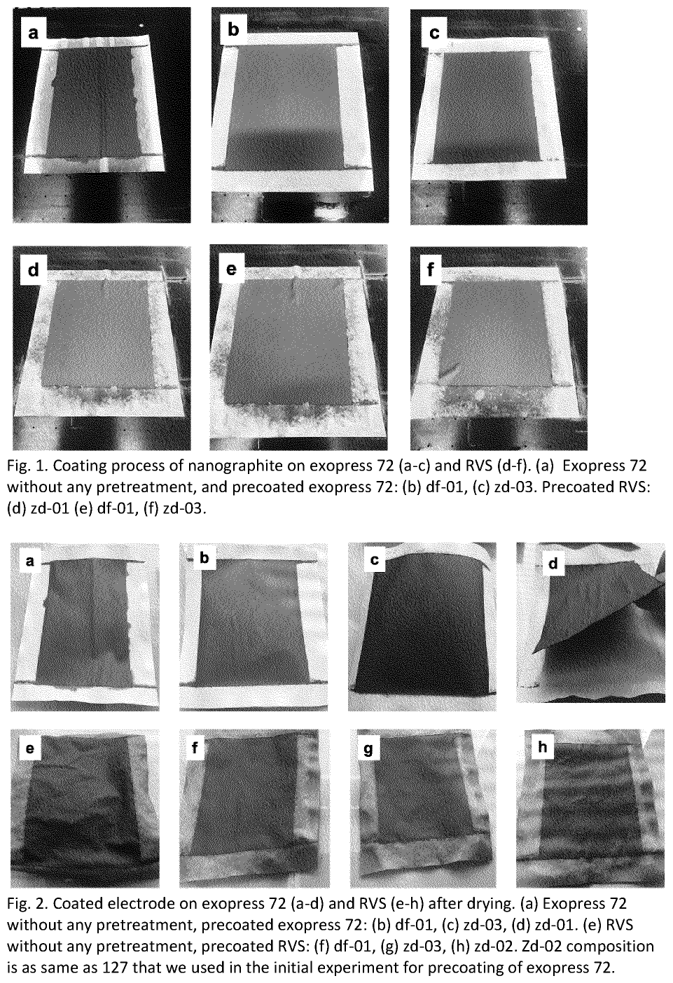

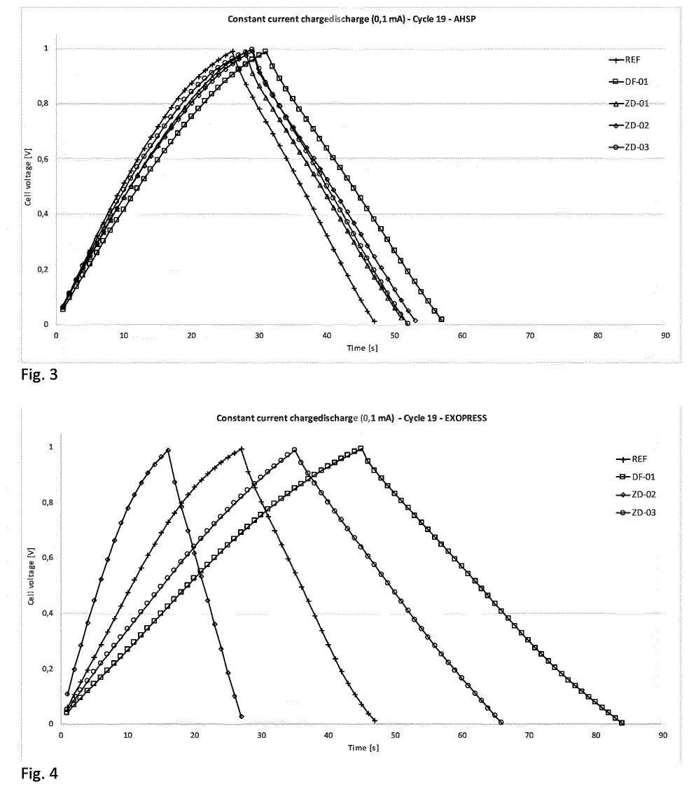

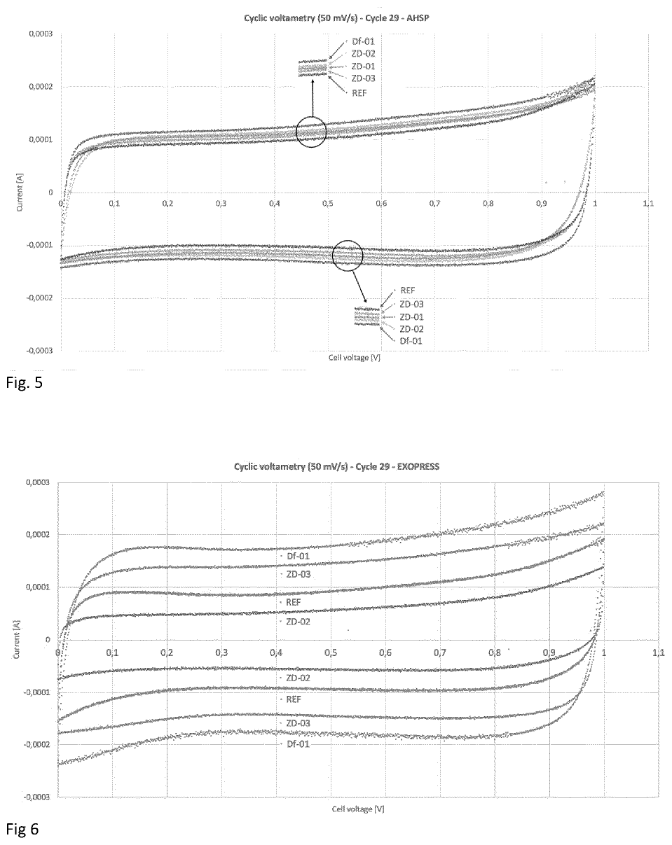

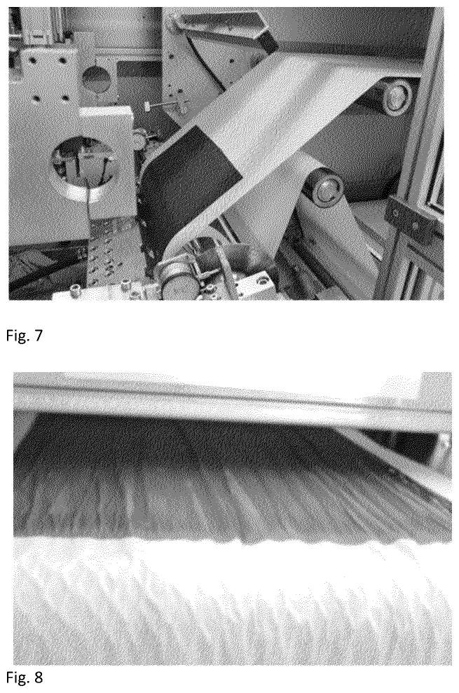

The results are shown in FIGS. 1 to 8.

### EXAMPLE 11

### Polymerization of Silanes

In to a 250 ml round-bottom flask, flushed with milli-Q water (200 ml), sodium dodecyl sulphate (2.3 g, 8 mmol) was added and stirred slowly for 30 minutes at room temperature. Then, citric acid (200 mg, 1 mmol) was added to the mixture, under stirring, and the solution was heated at 40° C. After 5 minutes, hexadecyltrimethoxysilane (85%, 14 g, 34 mmol) was added slowly. After 2 minutes, the stirring was stopped, while maintaining the heating at 40° C. for 2 hours. The heating was stopped, and the mixture was left for 46 hours at room temperature. The prepared suspension was stirred 1 hour at 1500 rpm.¹

Coating with the Water-Based Composition to Prepare Hydrophobic Substrates

The composition was applied on the surface using a spraying method. The modified surface was left at room temperature until the materials were adsorbed by the surface, this time varies between 10-20 minutes depending on the substrate. For the reaction between the chemicals and surface, Rapid-köthen sheet former was used at 93° C. at an applied pressure of 96 kPa for 20 minutes.¹ The treated surface is covered by 2-13 gram/m² material depending on the different formulation and different substrates.

Coating with Formulation Including Electron Conductive Material (e.g Graphene, Nanographite or an Electron Conducting Polymer)

The composition of electron conductive material was 95.2% water, 4.3%, nanographite, 0.4% TEMPO-oxidized kraft-pulp NFC and 0.1% poly-acrylic acid.

The nanographite was produced according to Blomquist et al.² as mentioned above with the S1 shear zone. ² The TEMPO-oxidized kraft-pulp NFC was produced according to previous publication by Saito et al.³

Two different paper substrates were used, pre-coated in step 1, one machine finished uncoated mechanical paper (EXOPRESS 72) and one high strength sack kraft paper (AHSP).

The electron conductive material was coated onto the pre-coated paper substrate using a standard Zehnter application frame with 250 mm wet coating thickness.

The coated samples were let to be dried at room temperature for 24 h.

After drying sheet, resistance measurements were performed followed by assembly and electrochemical measurements of standard symmetrical supercapacitor coin cells (CR2032). Galvanostatic cycling at constant current and cyclic voltammetry was performed on each sample.

### Examples for Pre-Coating Composition

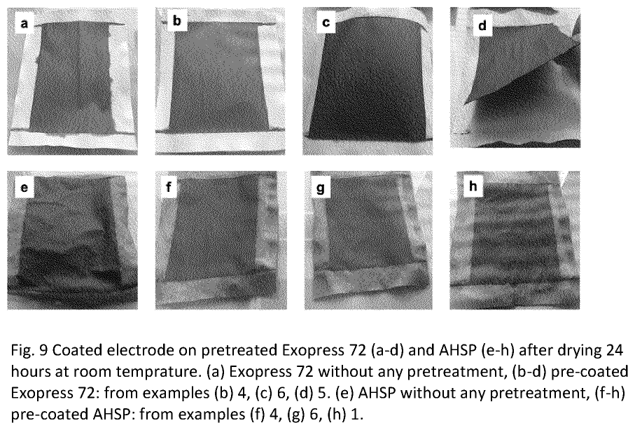

1. 2.3 g SDS (1% w/w), 0.2 g citric acid (0.09% w/w), 14 g hexadecyltrimethoxy silane (6.5% w/w), 200 g water. final pH=3.0.
2. 2.3 SDS (1% w/w), 0.4 g citric acid (0.18% w/w), 14 g hexadecyltrimethoxy silane (6.5% w/w), 200 g water. final pH=2.8.
3. 2.3 g SDS (1% w/w), 0.4 g citric acid (0.17% w/w), 28 g hexadecyltrimethoxy silane (12% w/w), 200 g water. final pH=2.8.
4. 2.3 g SDS (1% w/w), 0.15 g citric acid (0.17% w/w), 10.5 g hexadecyltrimethoxy silane (12% w/w), 200 g water. final pH=2.8.
   The results are shown in FIG. 9 and table 4.

TABLE 4
Electron conductivity of nanographite on catalytic pre-coated substrate.

| | | | | | | Capacitance |
|---|---|---|---|---|---|---|
| | Precoating | | Resistance | Capacitance | Discharge | specific * |
| Entry | experiment | Substrate | value(kOhm)^{a} | * 10⁻⁴ (F)^{b} | time (Second)^{b} | 10⁻¹(F/g)^{b} |
| 1^{c} | — | AHSP | 0.294 | 2.18 | 21.0 | 1.12 |
| 2 | 1 | AHSP | 0.181 | 2.59 | 25.0 | 1.52 |
| 3 | 2 | AHSP | 0.240 | 2.75 | 26.5 | 1.52 |
| 4 | 3 | AHSP | 0.239 | 2.33 | 22.5 | 1.16 |
| 5 | 4 | AHSP | 0.271 | 2.33 | 22.5 | 1.46 |
| 6^{c} | — | Exopress 72 | 0.338 | 2.02 | 19.5 | 1.44 |
| 7 | 1 | Exopress 72 | — | 1.14 | 11.0 | — |
| 8 | 2 | Exopress 72 | 0.175 | 4.10 | 39.5 | 1.78 |
| 9 | 4 | Exopress 72 | 0.189 | 2.95 | 28.5 | 1.73 |

^{a}Mean value of 10 measurement.
^{b}Mean value of two measurement.
^{c}Measurement on the substrate without pre-coating.

### REFERENCE

1. Cordova, A. and Alimohammadzadeh, R. 300438SE-S. 2020
2. Blomquist, N., Alimadadi, M., Hummelgård, M., Dahlström, C., Olsen, M., & Olin, H. (2019). Effects of geometry on large-scale tube-shear exfoliation of graphite to multilayer graphene and nanographite in water. Scientific reports, 9(1), 1-8.
3. Saito T, Hirota M, Tamura N, Kimura S, Fukuzumi H, Heux L, et al. Individualization of nano-sized plant cellulose fibrils by direct surface carboxylation using TEMPO catalyst under neutral conditions. Biomacromolecules. 2009; 10(7): 1992-1996.
   The present invention is not limited to the embodiments disclosed but may be varied and modified within the scope of the following claims.

1. An electron conducting coating comprising
I) a first coating prepared from a first composition comprising
1 to 15 wt % of a polymerized C₁₀₋₃₀alkanetriC₁₋₅alkoxysilane,
0.1 to 1.5 wt % of a surfactant,
0.01 to 0.40 wt % of an organic acid catalyst,
optionally 0.1 to 10 wt % of an inorganic component selected from the group comprising silica dioxide gel, pyrogenic silica, crystalline silica, titanium dioxide, and water glass (WGSi), and
up to 100 wt % water, wherein weight percentages are percentages of the total weight of the first composition, and
II) a second coating prepared from a second composition comprising 1 to 25 wt % of an electron conducting element selected from the group comprising graphene,
nanographite and an electron conducting polymer,
optionally, 0.1 to 10 wt % of an additive/binder,
optionally, 0.01 to 5 wt % of a dispersion agent, and
up to 100 wt % water, wherein weight percentages are percentages of the total weight of the second composition.

2. (canceled)

3. The coating according to claim 1, wherein the amounts of the ingredients are
5 to 13 wt % of a polymerized C₁₄₋₂₀alkanetrimethoxyalkoxysilane,
0.4 to 1.1 wt % of a surfactant,
0.05 to 0.30 wt % of an organic acid catalyst,
1 to 10 wt % of an electron conducting element,
optionally, 0 to 5 wt % of an additive/binder, and
optionally, 0.05 to 1 wt % of a dispersion agent.

4. The coating according to claim 1, wherein the polymerized silane is hexadecyltrimethoxysilane or octadecyltrimethoxysilane.

5. The coating according to claim 1, wherein an amount of polymerized silane is from 3 to 10 wt % when an inorganic component is present in the first composition or the amount of polymerized silane is from 5 to 15 wt % when no inorganic compound is present in the first composition.

6. The coating according to claim 1, wherein the organic acid catalyst is selected from the group comprising tartaric acid, citric acid, oxalic acid, fumaric acid, maleic acid and lactic acid and arylsulfonic acid.

7. The coating according to claim 5, wherein an amount of organic acid catalyst is from 0.01 to 0.3 wt %, when no inorganic component is present in the first composition.

8. (canceled)

9. The coating according to claim 1, wherein an amount of surfactant is from 0.6 to 0.9 wt % when an inorganic component is present in the first composition.

10. (canceled)

11. (canceled)

12. The coating according to claim 1, wherein the electron conducting polymer is selected from the group comprising polypyrrole (PPy), polyaniline (PANI), polythiophene (PTh), poly(3,4-ethylenedioxythiophene) (PEDOT) and their derivatives.

13-15. (canceled)

16. Use of the coating according to claim 1, for coating organic and inorganic surfaces.

17. (canceled)

18. The coating according to claim 5, wherein the amount of organic acid catalyst is from 0.02 to 0.2 wt %, when an inorganic component is present in the first composition.

19. The coating according to claim 1, wherein the amount of surfactant is from 0.5 to 1 wt %, when no inorganic component is present in the first composition.

20. A method for preparing an electron conducting coating comprising Step a) preparing a first coating from a first composition by catalytic hydrophobization using the steps of
a1) providing a solution of 0.1 to 1.5 wt % of surfactant and 0.04 to 0.40 wt % of an organic acid catalyst,
a2) adding 1 to 15 wt % of a polymerized C₁₀₋₃₀alkanetriC₁₋₅alkoxysilane until polymerized and homogenized,
a3) providing 0.1 to 10 wt % of an inorganic component selected from the group comprising silica dioxide gel, pyrogenic silica, crystalline silica, titanium dioxide, and water glass (WGSi),
a4) adding the 0.1 to 10 wt % solution of step a3) to the polymerized C₁₀₋₃₀alkanetriC₁₋₅alkoxysilane, and
up to 100 wt % water, wherein weight percentages are percentages of the total weight of the first composition,
a5) homogenizing the obtained mixture,
wherein weight percentages are percentages of the total weight of the first composition,
a6) applying the first composition on a surface, drying at room temperature using a heated sheet at a temperature above 40° C., at a pressure of at least 50 kPa for 10 to 30 minutes, and
Step b) Coating said surface with a second composition comprising electron conductive material using the steps of
b1) providing a second composition comprising 1 to 25 wt % of an electron conducting element selected from the group comprising graphene, nanographite and an electron conducting polymer,
optionally, 0.1 to 10 wt % of an additive/binder,
optionally, 0.01 to 5 wt % of a dispersion agent, and
up to 100 wt % water, wherein weight percentages are percentages of the total weight of the second composition,
b2) applying the second coating on the first coating followed by drying.

21. The method according to claim 20, wherein the amounts of the ingredients are
5 to 13 wt % of a polymerized C₁₄₋₂₀alkanetrimethoxyalkoxysilane,
0.4 to 1.1 wt % of a surfactant,
0.05 to 0.30 wt % of an organic acid catalyst,
1 to 10 wt % of an electron conducting element,
optionally, 0 to 5 wt % of an additive/binder, and
optionally, 0.05 to 1 wt % of a dispersion agent.

22. The method according to claim 20, wherein an amount of polymerized silane is from 3 to 10 wt %, when an inorganic component is present in the first composition or the amount of polymerized silane is from 5 to 15 wt %, when no inorganic compound is present in the first composition.

23. The method according to claim 20, wherein the organic acid catalyst is selected from the group comprising tartaric acid, citric acid, oxalic acid, fumaric acid, maleic acid and lactic acid and arylsulfonic acid.

24. The method according to claim 20, wherein an amount of organic acid catalyst is from 0.01 to 0.3 wt %, when no inorganic component is present in the first composition.

25. The method according to claim 20, wherein the amount of organic acid catalyst is from 0.02 to 0.2 wt %, when an inorganic component is present in the first composition.

26. The method according to claim 20, wherein an amount of surfactant is from 0.6 to 0.9 wt %, when an inorganic component is present in the first composition.

27. The method according to claim 20, wherein the amount of surfactant is from 0.5 to 1 wt %, when no inorganic component is present in the first composition.

28. The method according to claim 20, wherein the electron conducting polymer is selected from the group comprising polypyrrole (PPy), polyaniline (PANI), polythiophene (PTh), poly(3,4-ethylenedioxythiophene) (PEDOT) and their derivatives.
